(19) United States
(12) Patent Application Publication
(10) Pub. No.: US 2023/0420523 A1
(43) Pub. Date: Dec. 28, 2023

(54) SEMICONDUCTOR DEVICE

(71) Applicant: DENSO CORPORATION, Kariya-city (JP)

(72) Inventors: Yusuke HAYAMA, Kariya-city (JP); Yusuke YAMASHITA, Nagakute-city (JP); Keita KATAOKA, Nagakute-city (JP); Yukihiko WATANABE, Nagakute-city (JP)

(21) Appl. No.: 18/462,595

(22) Filed: Sep. 7, 2023

Related U.S. Application Data
(63) Continuation of application No. PCT/JP2021/048603, filed on Dec. 27, 2021.

(30) Foreign Application Priority Data
Mar. 22, 2021 (JP) 2021-046930

(51) Int. Cl. H01L 29/32; H01L 29/16; H01L 29/06; H01L 29/861; H01L 29/78

(52) U.S. Cl. CPC H01L 29/32; H01L 29/1608; H01L 29/7813; H01L 29/861; H01L 29/063

(57) ABSTRACT

A semiconductor device includes a first main electrode, a second main electrode, and a semiconductor layer. The semiconductor layer includes a p-type semiconductor region disposed at a position exposed from the upper surface of the semiconductor layer and electrically connected to the second main electrode, and an n-type semiconductor region in contact with the p-type semiconductor region and separated from the second main electrode by the p-type semiconductor region. The n-type semiconductor region has a trap region provided at a position in contact with the p-type semiconductor region, and a hole trap is formed in the trap region.

### CROSS REFERENCE TO RELATED APPLICATION

The present application is a continuation application of International Patent Application No. PCT/JP2021/048603 filed on Dec. 27, 2021, which designated the U.S. and claims the benefit of priority from Japanese Patent Application No. 2021-046930 filed on Mar. 22, 2021. The entire disclosures of all of the above applications are incorporated herein by reference.

### TECHNICAL FIELD

The present disclosure relates to a semiconductor device.

### BACKGROUND

When a forward bias is applied to a diode, electrons are injected from the n-type cathode region into the high resistance region, and holes are injected from the p-type anode region into the high resistance region.

### SUMMARY

According to an aspect of the present disclosure, a semiconductor device includes: a first main electrode; a second main electrode; and a semiconductor layer having a lower surface covered with the first main electrode and an upper surface covered with the second main electrode. The semiconductor layer includes: a p-type semiconductor region disposed at a position exposed from the upper surface and electrically connected to the second main electrode; and an n-type semiconductor region in contact with the p-type semiconductor region and separated from the second main electrode by the p-type semiconductor region. The n-type semiconductor region has a trap region provided at a position in contact with the p-type semiconductor region. A hole trap is formed in the trap region.

### BRIEF DESCRIPTION OF THE DRAWINGS

FIG. 1 is a schematic sectional view illustrating a diode according to an embodiment.

FIG. 2 is a graph illustrating a relationship between concentration of aluminum and n-type impurities in a depth direction of a semiconductor layer.

FIG. 3 is a diagram illustrating effects of a trap region at a forward bias time, in which (A) represents a density of holes trapped in a hole trap, and (B) represents a potential of the trap region.

FIG. 4 is a graph illustrating a relationship between concentration of aluminum and n-type impurities in a depth direction of a semiconductor layer.

FIG. 5 is a schematic sectional view illustrating a MOSFET according to an embodiment.

### DETAILED DESCRIPTION

When a forward bias is applied to a diode such as in-MOSFET diode, electrons are injected from the n-type cathode region into the high resistance region, and holes are injected from the p-type anode region into the high resistance region. When the voltage applied to the diode changes from the forward bias to the reverse bias, the electrons and the holes injected into the high resistance region at the time of the forward bias move in the opposite direction to those at the time of the forward bias. Such a flow of electrons and holes in the opposite direction is called a recovery current and is a main cause of recovery loss.

In case where a diode is formed using silicon carbide, when holes injected into a high resistance region reach an n-type cathode region and electrons and holes recombine in the n-type cathode region, defects grow at an interface between the n-type cathode region and the high resistance region due to the recombination energy.

In order to suppress such an increase in recovery loss or growth of stacking faults, it is possible to suppress the concentration of the holes in the high resistance region when the diode receives the forward bias. For example, a Z_{1/2} center derived from a C vacancy is formed in a high resistance region to reduce a carrier lifetime of the high resistance region, thereby suppressing holes injected into the high resistance region from reaching the n-type cathode region.

The concentration of the holes in the high resistance region can be kept low by promoting recombination of electrons and holes injected into the high resistance region. However, as a result of studies by the present inventors, it has been found that the technique cannot suppress injection of holes from the p-type anode region when the diode is forward biased. The present disclosure provides a technique for suppressing the hole injection itself when a diode is forward biased.

According to an aspect of the present disclosure, a semiconductor device includes: a first main electrode; a second main electrode; and a semiconductor layer having a lower surface covered with the first main electrode and an upper surface covered with the second main electrode. The semiconductor layer includes: a p-type semiconductor region disposed at a position exposed from the upper surface and electrically connected to the second main electrode; and an n-type semiconductor region in contact with the p-type semiconductor region and separated from the second main electrode by the p-type semiconductor region. The n-type semiconductor region has a trap region provided at a position in contact with the p-type semiconductor region. A hole trap is formed in the trap region.

In the semiconductor device, the trap region in which a hole trap is formed is provided at a position in contact with the p-type semiconductor region. Therefore, when the semiconductor device is forward biased, the trap region forms an energy barrier for holes, so that injection of holes from the p-type semiconductor region into the n-type semiconductor region can be suppressed.

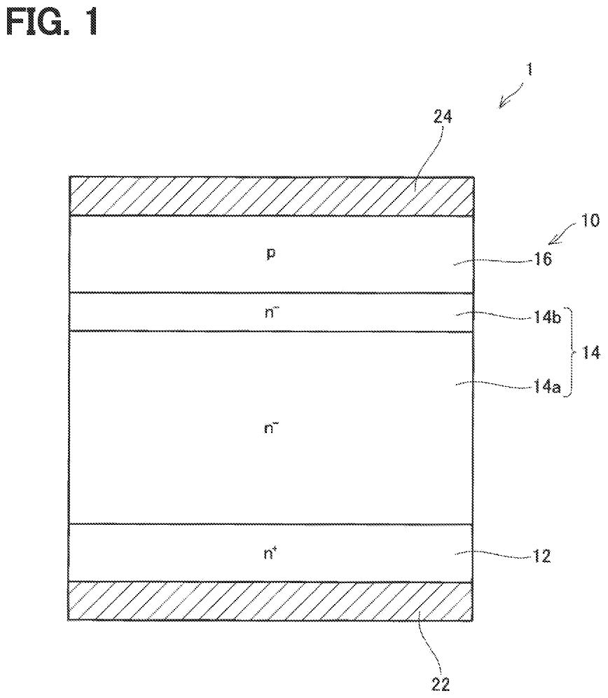

As shown in FIG. 1, a diode 1 includes a semiconductor layer 10, a cathode electrode 22 covering the lower surface of the semiconductor layer 10, and an anode electrode 24 covering the upper surface of the semiconductor layer 10. The material of the cathode electrode 22 and the anode electrode 24 may be, for example, Al, Ni, Ti, Mo, or Co. The cathode electrode 22 is a first main electrode, and the anode electrode 24 is a second main electrode.

The semiconductor layer 10 is made of silicon carbide (SiC) and includes an n⁺ type cathode region 12, an n⁻ high resistance region 14, and a p-type anode region 16.

The cathode region 12 is disposed at a position exposed to the lower surface of the semiconductor layer 10, and is in ohmic contact with the cathode electrode 22. The cathode region 12 is, for example, a silicon carbide substrate having a plane orientation of (0001), and is also a base substrate for epitaxially growing the high resistance region 14 as described later.

The high resistance region 14 is disposed between the cathode region 12 and the anode region 16, and is in contact with both the cathode region 12 and the anode region 16. The high resistance region 14 is separated from the cathode electrode 22 by the cathode region 12, and is separated from the anode electrode 24 by the anode region 16. The high resistance region 14 is made of silicon carbide formed by crystal growth from the surface of the cathode region 12 using an epitaxial growth technique, and the concentration of the n-type impurity is lower than that of the cathode region 12. The high resistance region 14 is an example of an n-type semiconductor region.

The high resistance region 14 includes a non-trap region 14a and a trap region 14b. The non-trap region 14a is disposed between the cathode region 12 and the trap region 14b, and is in contact with the cathode region 12. The trap region 14b is disposed between the anode region 16 and the non-trap region 14a, and is in contact with the anode region 16.

A hole trap is not substantially formed in the non-trap region 14a. A hole trap is formed in the trap region 14b. The hole trap is formed at a deep energy level in the band gap by a defect, an impurity, or the like, and capable of trapping holes. Information such as the energy level, density, and depth of the hole trap can be obtained by a deep level transient spectroscopy (DLTS) method. The method of forming the hole trap is not particularly limited. For example, in the diode 1 of the present embodiment, a hole trap is formed by introducing aluminum into a range corresponding to the trap region 14b in the high resistance region 14 using an ion implantation technique.

The anode region 16 is disposed at a position exposed to the upper surface of the semiconductor layer 10, and is in ohmic contact with the anode electrode 24. The method of forming the anode region 16 is not particularly limited. For example, in the diode 1 of the present embodiment, the anode region 16 is formed in the upper layer portion of the high resistance region 14 formed by crystal growth by introducing a p-type impurity having a higher concentration than the n-type impurity of the high resistance region 14 in multiple stages while changing the range distance using an ion implantation technique. As the p-type impurity, for example, aluminum is used. The anode region 16 is an example of p-type semiconductor region.

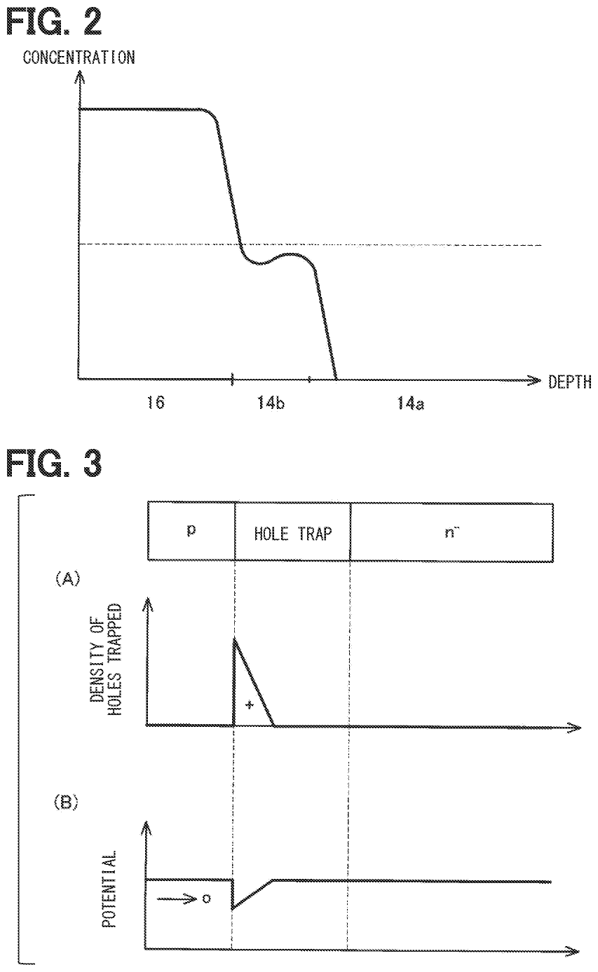

FIG. 2 shows the concentration distribution of aluminum in the depth direction of the semiconductor layer 10. The range of the reference numeral “16” represents the anode region 16, the range of the reference numeral “14b” represents the range of the trap region 14b, and the range of the reference numeral “14a” represents the range of the non-trap region 14a. The broken line indicates the concentration of the n-type impurity contained in the semiconductor layer 10.

The anode region 16 contains more aluminum than the n-type impurity. Therefore, the anode region 16 is p-type. Although FIG. 2 shows that the concentration of aluminum contained in the anode region 16 is constant in the depth direction, since aluminum is introduced by multistage ion implantation as described above, plural peaks actually exist apart from each other in the depth direction.

The trap region 14b contains less aluminum than the n-type impurity. Therefore, the trap region 14b is n-type. As shown in FIG. 2, the concentration distribution of aluminum has a step in a range corresponding to the trap region 14b. At the step of the concentration distribution, the decrease in the concentration in the depth direction is suppressed, as compared with the upper and lower ranges. More specifically, the decrease in the concentration in the depth direction does not occur in the step. As described above, since the trap region 14b is formed by ion implantation of aluminum, the peak of the concentration of aluminum in the depth direction is located in the trap region 14b. Therefore, the trap region 14b includes a portion where the concentration of aluminum increases.

It is known that a hole trap is formed in a region into which aluminum is introduced. The density of the hole traps is generally proportional to the concentration of aluminum. Therefore, the density distribution of the hole traps in the depth direction of the semiconductor layer 10 shows the same distribution as the concentration distribution of aluminum shown in FIG. 2. Therefore, it can be said that the trap region 14b is an n-type region including the peak of the density distribution of the hole traps in the depth direction. It can also be said that the trap region 14b is an n-type region in which the density of hole traps is 10¹⁴ cm⁻³ or more, and more preferably in which the density of hole traps is 10¹⁶ cm⁻³ or more.

The operation of the diode 1 will be described. When a forward bias is applied between the cathode electrode 22 and the anode electrode 24 so that the anode electrode 24 has a higher potential than the cathode electrode 22, electrons are injected from the cathode region 12 into the high resistance region 14. Holes are injected from the anode region 16 into the high resistance region 14, and electrical continuity is established between the cathode electrode 22 and the anode electrode 24. Next, when a reverse bias is applied between the cathode electrode 22 and the anode electrode 24 so that the anode electrode 24 has a lower potential than the cathode electrode 22, electrons and holes injected into the high resistance region 14 at the time of the forward bias move in the opposite direction opposite to those at the time of the forward bias. Such a flow of electrons and holes in the opposite direction is called a recovery current.

The operation of the trap region 14b at the time of forward bias will be described with reference to FIG. 3. The region of “p” in FIG. 3 corresponds to the anode region 16, the region of “hole trap” corresponds to the trap region 14b, and the region of “n⁻” corresponds to the non-trap region 14a. When the forward bias is applied, holes are trapped in the hole traps of the trap region 14b, and the density of the holes trapped in the trap region 14b increases (see (A) of FIG. 3). When the holes are trapped by the hole traps, the potential of the hole traps increases, and a potential barrier against the holes is formed in the trap region 14b (see (B) of FIG. 3). Thus, injection of holes from the anode region 16 into the high resistance region 14 is suppressed. Since the injection of holes from the anode region 16 into the high resistance region 14 is suppressed, the hole concentration of the high resistance region 14 at the time of forward bias can be suppressed to be low. As a result, the recovery current when the reverse bias is applied is suppressed, and the recovery loss is reduced.

Further, in the diode 1 of the present embodiment, when the energy level of the hole trap of the trap region 14b is denoted by Et, the energy level of the valence band of the trap region 14b is denoted by Ev, and the band gap of the trap region 14b is denoted by Eg, a relationship of Et−Ev<Eg/2 is established. That is, the formula of Et-Ev is smaller than the mid band gap. The energy level Et of the hole trap formed by ion implantation of aluminum may have such a relationship. The hole trap having the energy level that satisfies such a relationship does not trap the holes at zero bias. Therefore, in the diode 1, decrease in breakdown voltage due to charged hole traps does not occur.

In the diode 1 of the present embodiment, the high resistance region 14 includes the non-trap region 14a. By providing the non-trap region 14a, it is possible to suppress an increase in forward voltage as compared with a case where hole traps are formed in the entire high resistance region 14. Therefore, the diode 1 of the present embodiment can suppress the recovery loss while suppressing the increase in the forward voltage.

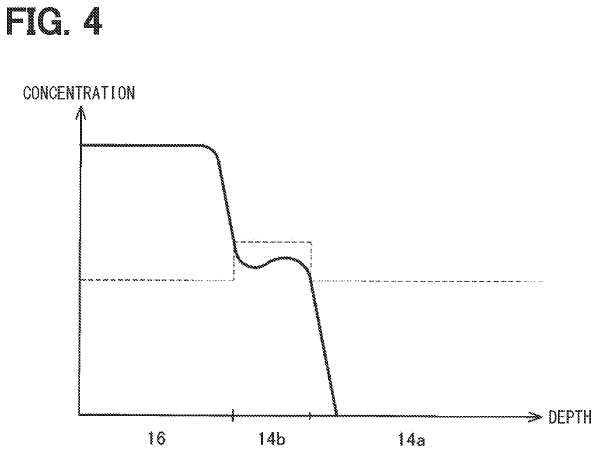

As illustrated in FIG. 4, by setting the concentration of the n-type impurity in the trap region 14b to be higher than the concentration of the n-type impurity in the non-trap region 14a, the concentration of aluminum included in the trap region 14b can also be increased. In this example, the concentration of aluminum in the trap region 14b is higher than the concentration of n-type impurities in the non-trap region 14a. As described above, when the concentration of aluminum in the trap region 14b is high, the density of hole traps is also high, and injection of holes at the time of forward bias can be effectively suppressed. In order to selectively increase the concentration of the n-type impurity in the trap region 14b, for example, when the high-resistance region 14 is epitaxially grown, the concentration of the n-type impurity in a range corresponding to the trap region 14b may be increased, or the n-type impurity may be ion-implanted into the range corresponding to the trap region 14b after the epitaxial growth.

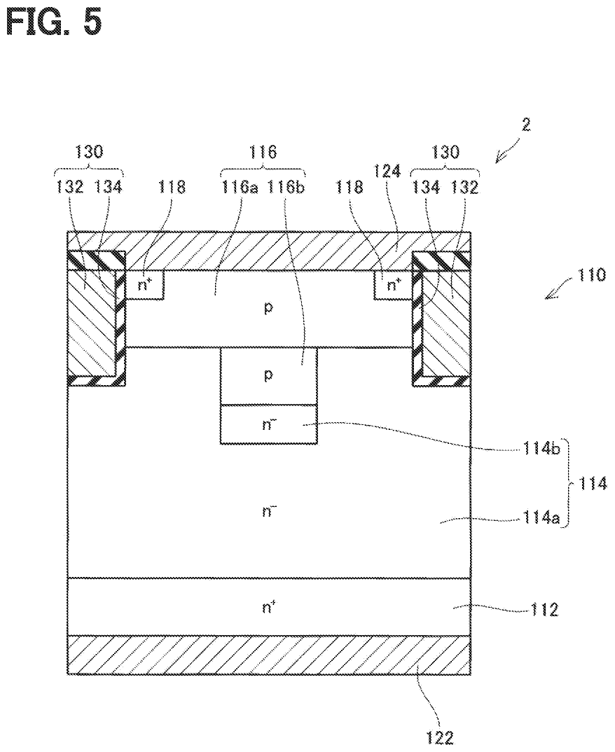

Hereinafter, a MOSFET (Metal Oxide Semiconductor Field Effect Transistor) 2 including a diode will be described with reference to FIG. 5. The MOSFET 2 is used, for example, in an inverter device that supplies AC power to an AC motor, and a built-in diode operates as a freewheel diode.

As shown in FIG. 5, the MOSFET 2 includes a semiconductor layer 110, a drain electrode 122 covering the lower surface of the semiconductor layer 110, a source electrode 124 covering the upper surface of the semiconductor layer 110, and a trench gate portion 130 provided in the upper layer portion of the semiconductor layer 110. As the material of the drain electrode 122 and the source electrode 124, for example, Al, Ni, Ti, Mo, or Co may be used. Note that the drain electrode 122 is an example of a first main electrode, and the source electrode 124 is an example of a second main electrode.

The semiconductor layer 110 is made of silicon carbide (SiC), and includes an n+ drain region 112, an n− high resistance region 114, a p-type body region 116, and an n+ source region 118.

The drain region 112 is disposed at a position exposed to the lower surface of the semiconductor layer 110, and is in ohmic contact with the drain electrode 122. The drain region 112 is a silicon carbide substrate having a (0001) plane orientation, and is also a base substrate for epitaxially growing the high resistance region 114.

The high resistance region 114 is disposed between the drain region 112 and the body region 116, and is in contact with both the drain region 112 and the body region 116. The high resistance region 114 is separated from the drain electrode 122 by the drain region 112, and is separated from the source electrode 124 by the body region 116. The high resistance region 114 is made of silicon carbide formed by crystal growth from the surface of the drain region 112 using an epitaxial growth technique, and the concentration of the n-type impurity is lower than that of the drain region 112. The high resistance region 114 is an example of an n-type semiconductor region.

The high resistance region 114 includes a non-trap region 114a and a trap region 114b. The non-trap region 114a is disposed between the drain region 112 and the trap region 114b, and is in contact with the drain region 112. The trap region 114b is disposed between the body region 116 and the non-trap region 114a, and is in contact with the body region 116. No hole trap is formed in the non-trap region 114a. A hole trap is formed in the trap region 114b. The concentration distribution of aluminum and the density distribution of hole traps in the trap region 114b are similar to those in the trap region 14b of the diode 1.

The body region 116 is disposed at a position exposed to the upper surface of the semiconductor layer 110, and is in ohmic contact with the source electrode 124. The body region 116 includes a main body region 116a and an electric field relaxation region 116b. The main body region 116a is disposed at a position exposed to the upper surface of the semiconductor layer 110, and is in contact with the side surface of the trench gate portion 130. The electric field relaxation region 116b is disposed in contact with the bottom surface of the main body region 116a and away from the side surface of the trench gate portion 130. The electric field relaxation region 116b is formed so as to protrude downward of the bottom surface of the trench gate portion 130. When such an electric field relaxation region 116b is formed, the electric field of the bottom surface of the trench gate portion 130 can be relaxed when the MOSFET 2 is turned off.

The method of forming the body region 116 is not particularly limited. For example, in the MOSFET 2 of the present embodiment, the body region 116 is formed in the upper layer portion of the high resistance region 114 formed by epitaxial growth by introducing a p-type impurity having a higher concentration than the n-type impurity of the high resistance region 114 in multiple stages while changing the range distance using an ion implantation technique. As the p-type impurity, for example, aluminum is used. Note that the body region 116 is an example of a p-type semiconductor region.

The source region 118 is disposed at a position exposed to the upper surface of the semiconductor layer 110. The source region 118 is provided on the body region 116, and is separated from the high resistance region 114 by the body region 116. The method of forming the source region 118 is not particularly limited. In the MOSFET 2 of the present embodiment, the source region 118 is formed by introducing an n-type impurity into the upper layer portion of the semiconductor layer 110 using an ion implantation technique.

The trench gate portion 130 faces a part of the main body region 116a separating the non-trap region 114a of the high resistance region 114 from the source region 118. The trench gate portion 130 includes a trench gate electrode 132 and a gate insulating film 134 provided in a trench that penetrates the source region 118 and the main body region 116a from the upper surface of the semiconductor layer 110 and reaches the non-trap region 114a of the high resistance region 114. The trench gate electrode 132 is formed by filling a trench covered with the gate insulating film 134 using a CVD technique. The gate insulating film 134 is formed by coating the inner wall of the trench using a CVD technique.

The MOSFET 2 includes a diode in which the drain region 112 corresponds to an anode region and the body region 116 corresponds to a cathode region. The built-in diode operates as a freewheel diode. The operation and effect when the built-in diode operates are the same as those of the diode 1. That is, by providing the trap region 114b, injection of holes from the body region 116 into the high resistance region 114 during forward bias is suppressed, and the hole concentration of the high resistance region 14 can be suppressed to be low. As a result, the recovery current when the reverse bias is applied is suppressed, and the recovery loss is reduced. In the MOSFET 2, the trap region 114b is selectively formed so as to be in contact with the bottom surface of the electric field relaxation region 116b of the body region 116. The injection of holes from the body region 116 is mainly performed from the electric field relaxation region 116b. Therefore, even if the trap region 114b is selectively provided with respect to the electric field relaxation region 116b, injection of holes from the body region 116 into the high resistance region 114 can be effectively suppressed.

In the MOSFET 2, the trap region 114b is disposed away from the side surface of the trench gate portion 130. Therefore, the trap region 114b is disposed away from the channel formed on the side surface of the trench gate portion 130 when the MOSFET 2 is turned on. As a result, an increase in the channel resistance of the MOSFET 2 is suppressed. Thus, the MOSFET 2 can suppress an increase in the recovery current while suppressing an increase in the channel resistance.

The features of the techniques disclosed in the present disclosure are described below. It should be noted that the technical elements described below are independent technical elements and exhibit technical usefulness alone or in various combinations, and are not limited to the combinations described in the present description at the time of filing.

According to an aspect of the present disclosure, a semiconductor device includes a first main electrode, a second main electrode, and a semiconductor layer. The semiconductor layer has a lower surface covered with the first main electrode and an upper surface covered with the second main electrode. The semiconductor layer may include a p-type semiconductor region and an n-type semiconductor region. The p-type semiconductor region is disposed at a position exposed from the upper surface and is electrically connected to the second main electrode. The n-type semiconductor region is in contact with the p-type semiconductor region and is separated from the second main electrode by the p-type semiconductor region. The n-type semiconductor region includes a trap region provided at a position in contact with the p-type semiconductor region. A hole trap is formed in the trap region. The semiconductor device may be a diode or a diode built in a MOSFET.

In the semiconductor device, a density distribution of the hole traps in a depth direction of the semiconductor layer may have a peak in a range corresponding to the trap region. In the semiconductor device, a hole trap is intentionally formed in a range corresponding to the trap region using, for example, an ion implantation technique or the like.

In the semiconductor device, the relationship Et−Ev<Eg/2 may be established when the energy level of the hole trap of the trap region is defined as Et, the energy level of the valence band of the trap region is defined as Ev, and the band gap of the trap region is defined as Eg. According to the semiconductor device, a decrease in breakdown voltage is suppressed.

The semiconductor layer may be silicon carbide. Accordingly, when the forward bias is applied, since the hole concentration of the n-type semiconductor region is suppressed, the growth of stacking faults, which is a matter inherent to silicon carbide, is also suppressed.

The trap region may contain aluminum. In silicon carbide, it is known that a hole trap is formed by introducing aluminum. Therefore, a hole trap is formed in the trap region containing aluminum.

The concentration distribution of the n-type impurity in the n-type semiconductor region may be higher in a range corresponding to the trap region than in other ranges. By increasing the concentration of the n-type impurity in the trap region, the concentration of aluminum in the trap region can be increased while maintaining the n-type. Therefore, the trap region can also increase the density of hole traps.

The semiconductor device may further include a trench gate portion provided in a trench that penetrates the p-type semiconductor region from the upper surface of the semiconductor layer to the n-type semiconductor region. The trap region may be disposed at a position away from a side surface of the trench gate portion. Accordingly, it is possible to suppress an increase in recovery current while suppressing an increase in channel resistance.

The p-type semiconductor region may include an electric field relaxation region protruding downward of a bottom surface of the trench gate portion at a position away from the side surface of the trench gate portion. The trap region may be disposed in contact with a bottom surface of the electric field relaxation region. Accordingly, it is possible to suppress an increase in recovery current while suppressing an increase in channel resistance.

Although specific examples of the present disclosure have been described in detail above, these are merely examples and do not limit the scope of claims. The techniques described in the claims include various modifications and modifications of the specific examples illustrated above. In addition, the technical elements described in the present description or the drawings exhibit technical usefulness alone or in various combinations, and are not limited to the combinations described in the present description at the time of filing. In addition, the techniques illustrated in the present specification or drawings can achieve multiple purposes at the same time, and has technical usefulness by achieving one of the purposes.

What is claimed is:

1. A semiconductor device comprising:
a first main electrode;
a second main electrode; and
a semiconductor layer having a lower surface covered with the first main electrode and an upper surface covered with the second main electrode, wherein the semiconductor layer includes
a p-type semiconductor region disposed at a position exposed from the upper surface and electrically connected to the second main electrode, and
an n-type semiconductor region in contact with the p-type semiconductor region and separated from the second main electrode by the p-type semiconductor region,
the n-type semiconductor region has a trap region at a position in contact with the p-type semiconductor region,
a hole trap is formed in the trap region,
an energy level of the hole trap of the trap region is represented by Et,
an energy level of a valence band of the trap region is represented by Ev,
a band gap of the trap region is represented by Eg, and
a relationship of Et−Ev<Eg/2 is established.

2. The semiconductor device according to claim 1, wherein a density distribution of the hole trap in a depth direction of the semiconductor layer has a peak in a range corresponding to the trap region.

3. The semiconductor device according to claim 1, wherein the semiconductor layer is silicon carbide.

4. The semiconductor device according to claim 3, wherein the trap region contains aluminum.

5. The semiconductor device according to claim 4, wherein a concentration distribution of an n-type impurity in the n-type semiconductor region is higher in a range corresponding to the trap region than in the other range.

6. The semiconductor device according to claim 1 further comprising a trench gate portion provided in a trench extending from the upper surface of the semiconductor layer through the p-type semiconductor region to reach the n-type semiconductor region, wherein
the trap region is disposed at a position away from a side surface of the trench gate portion.

7. The semiconductor device according to claim 6, wherein
the p-type semiconductor region includes an electric field relaxation region protruding downward of a bottom surface of the trench gate portion at a position away from the side surface of the trench gate portion, and
the trap region is disposed in contact with a bottom surface of the electric field relaxation region.

8. The semiconductor device according to claim 1, further comprising a trench gate portion provided in a trench extending from the upper surface of the semiconductor layer through the p-type semiconductor region to reach the n-type semiconductor region, wherein
the p-type semiconductor region includes an electric field relaxation region protruding downward of a bottom surface of the trench gate portion at a position away from a side surface of the trench gate portion, and
the trap region is disposed in contact with a bottom surface of the electric field relaxation region.

9. The semiconductor device according to claim 8, wherein a concentration distribution of an n-type impurity in the n-type semiconductor region is higher in a range corresponding to the trap region than in the other range.

10. A semiconductor device comprising:
a first main electrode;
a second main electrode; and
a semiconductor layer having a lower surface covered with the first main electrode and an upper surface covered with the second main electrode, wherein
the semiconductor layer includes
a p-type semiconductor region disposed at a position exposed from the upper surface and electrically connected to the second main electrode, and
an n-type semiconductor region in contact with the p-type semiconductor region and separated from the second main electrode by the p-type semiconductor region,
the n-type semiconductor region has a trap region provided at a position in contact with the p-type semiconductor region,
a hole trap is formed in the trap region,
the semiconductor layer is silicon carbide, and
the trap region contains aluminum.

11. A semiconductor device comprising:
a first main electrode;
a second main electrode; and
a semiconductor layer having a lower surface covered with the first main electrode and an upper surface covered with the second main electrode, wherein
the semiconductor layer includes
a p-type semiconductor region disposed at a position exposed from the upper surface and electrically connected to the second main electrode, and
an n-type semiconductor region in contact with the p-type semiconductor region and separated from the second main electrode by the p-type semiconductor region,
the n-type semiconductor region has a trap region provided at a position in contact with the p-type semiconductor region,
a hole trap is formed in the trap region,
the semiconductor device further comprising a trench gate portion provided in a trench extending from the upper surface of the semiconductor layer through the p-type semiconductor region to reach the n-type semiconductor region, and
the trap region is disposed at a position away from a side surface of the trench gate portion.
